(19) United States
(12) Patent Application Publication
(10) Pub. No.: US 2008/0084233 A1
(43) Pub. Date: Apr. 10, 2008

(54) FREQUENCY REGULATOR HAVING LOCK DETECTOR AND FREQUENCY REGULATING METHOD

(75) Inventor: Soon-Seob Lee, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/755,836

(22) Filed: May 31, 2007

(30) Foreign Application Priority Data
Oct. 4, 2006 (KR) 10-2006-0097486

(51) Int. Cl. H03L 7/06

(52) U.S. Cl. 327/156; 327/155

(57) ABSTRACT

A frequency regulator including a phase frequency detector and a lock detection unit. The phase frequency detector receives a reference signal and a feedback signal, compares a phase of the reference signal and a phase of the feedback signal, and outputs a first control signal and a second control signal to regulate phase and frequency of the feedback signal. The lock detection unit generates a phase lock signal in a case of keeping that a time difference between the first control signal and the second control signal is smaller than a reference time during an interval time period of at least a half period of the reference signal.

### CROSS-REFERENCE TO RELATED APPLICATION

This U.S. non-provisional patent application claims priority under 35 U.S.C. §119 from Korean Patent Application No. 10-2006-0097486, filed on Oct. 4, 2006, the entire contents of which are hereby incorporated by reference.

### BACKGROUND OF THE INVENTION

1. Field of the Invention

Embodiments of the invention relate to a frequency regulator and more particularly, to a frequency regulator having a lock detector and associated frequency regulating method.

2. Discussion of Related Art

PLLs (phase locked loops) or DLLs (delay locked loops) generate an output signal synchronized in frequency and phase with a reference signal. “Phase lock” signifies that the phase frequency of an output signal of the PLL or DLL is synchronized with a phase frequency of the reference signal. “Phase lock time” is defined as a time until the phase lock after the PLL or DLL is reset.

FIG. 1 is a timing diagram to explain conventional phase lock timing. A conventional PLL's phase lock time is defined by a predetermined clock, for example, 200-20,000 cycles, of an output signal “fvco” of a PLL. An electronic system having the PLL or DLL determines whether the PLL or DLL is in an unlock state until the phase lock time passes. However, conventional technology has the following drawbacks. First, although the phase of the PLL or DLL is already locked before the phase lock time, the time for initializing the PLL of DLL can be delayed since the PLL or DLL uses unnecessary clocks before the phase lock time passes. Second, when a latency related clock is prepared using the PLL or DLL, setting the latency clock may be complicated since it needs to be set before the phase lock time passes. Third, since the degree of jitter affecting the time difference between the frequency of the reference signal and the frequency of the output signal of the PLL or DLL cannot be recognized, there is no method to recognize an operation state of the PLL or DLL making it difficult to know when the PLL or DLL is unlocked.

### SUMMARY OF THE INVENTION

Exemplary embodiments of the present invention are directed to a frequency regulator which determines the phase lock of a PLL or DLL, measures the phase lock time, and accurately sets internal latency using signals of the PLL or DLL. The frequency regulator determines the degree of jitter that affects the time difference between the reference signal and the output signal and recognizes the operation state of a PLL or DLL, as well as an associated frequency regulating method.

The frequency regulator includes a phase frequency detector for receiving a reference signal and a feedback signal. The phase frequency detector compares a phase associated with the received reference signal and a phase associated with the received feedback signal and outputs a first control signal and a second control signal to regulate the phase and frequency of the feedback signal. A lock detection unit is coupled to the phase frequency detector and generates a phase lock signal when a time difference between the first control signal and the second control signal is smaller than a reference time during an interval time period of at least a half period of the reference signal.

### BRIEF DESCRIPTION OF THE DRAWINGS

FIG. 1 is a timing diagram for explaining conventional phase lock time;

FIG. 2 is a functional block diagram of a PLL according to an embodiment of the present invention;

FIG. 3 is a circuit diagram of a phase frequency detector of the PLL of FIG. 2;

FIG. 4 is a circuit diagram of a lock detection unit of the PLL of FIG. 2;

FIG. 5 is a timing diagram showing the operation of the PLL of FIG. 2;

FIG. 6 is a timing diagram for explaining a phase lock time according to an embodiment of the present invention; and

FIG. 7 is a functional block diagram of a DLL according to an embodiment of the present invention.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

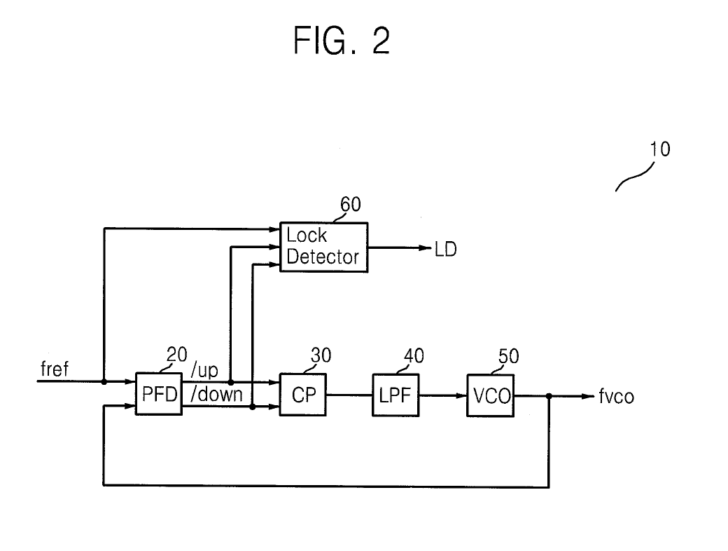

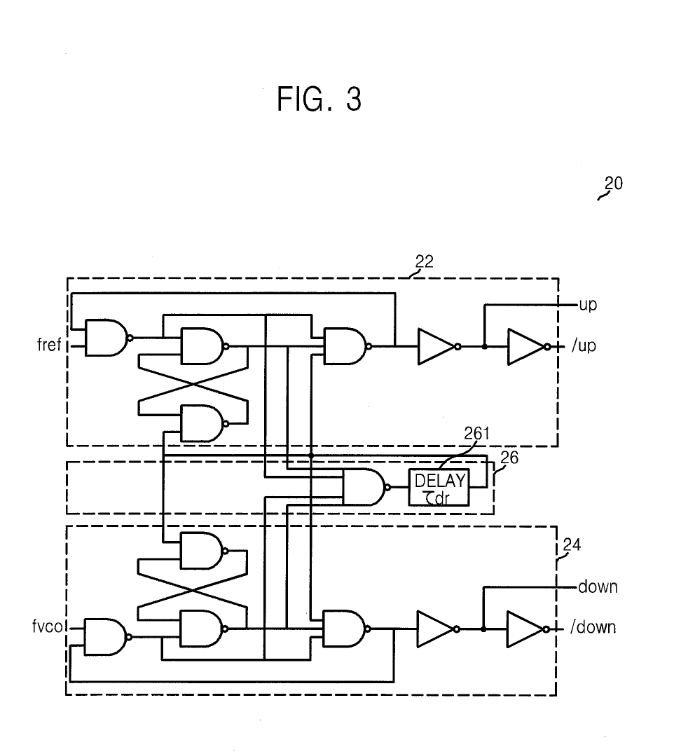

FIG. 2 is a functional block diagram of a Phase Locked Loop (PLL) 10 according to an embodiment of the present invention and FIG. 3 is a circuit diagram of phase frequency detector 20 of PLL 10. PLL 10 includes phase frequency detector (PFD) 20, charge pump (CP) 30, low pass filter (LPF) 40, voltage controlled oscillator (VCO) 50, and lock detector 60. PFD 20 receives reference signal “fref” and a feedback signal “fvco” output from VCO 50, compares phases of the received signals, and outputs a first control signal “/up” or a second control signal “/down” corresponding to the comparison result to CP 30 and lock detector 60. PFD 20 includes a first control signal generating unit 22, a second control signal generating unit 24, and a reset unit 26 shown in FIG. 3.

First control signal generating unit 22 may comprise a series of NAND and inverter gates configured to compare the phases of reference signal “fref” and feedback signal “fvco”. When the phase of feedback signal “fvco” leads the phase of reference signal “fref”, first control signal generating unit 22 generates first control signal “/up” to increase the frequency of feedback signal “fvco”. Second control signal generating unit 24 may also comprise a series of nand and inverter gates configured to compare the phases of reference signal “fref” and feedback signal “fvco”. When the phase of feedback signal “fvco” lags behind the phase of reference signal “fref”, second control signal generating unit 24 generates second control signal “/down” to decrease the frequency of feedback signal “fvco”. Reset unit 26 resets PFD 20 using second control signal “/down” generated after first control signal “/up” as a reset signal. Also, reset unit 26 resets PFD 20 using first control signal “/up” generated after the second control signal “/down” as a reset signal.

Delay unit 261 delays first control signal “/up” and second control signal “/down” for a predetermined time “Tdr” to prevent generation of a dead zone where the gain of PFD 20 is “0” during the reset operation of reset unit 26. PFD 20 compares the phase of reference signal “fref” with the phase of feedback signal “fvco’ and generates first control signal “/up” or second control signal “/down” based on this comparison result. The time difference between the phase of the “up” signal and first control signal “/up” is 180°. Similarly, the time difference between the phase of the “down” signal and second control signal “/down” is 180°. Reference signal “fref” is output from a crystal oscillator (not shown) that generates a fixed stable frequency. CP 30 supplies a predetermined current or charge to LPF 40 in response to first control signal “/up” and discharges current or charge stored in a capacitor of LPF 40 in response to second control signal “/down”. LPF 40 is, for example, a loop filter that removes high frequency noise included in the current supplied from CP 30 and generates an analog control voltage. VCO 50 generates the output signal “fvco” based on this analog control voltage.

Lock detector 60 generates a phase lock signal “LD” when the time difference between first control signal “/up” and second control signal “/down” output from PFD 20 is smaller than the time interval of at least a half period of reference signal “fref”. The reference time is a value preset according to design rules. The feedback signal “fvco” may be locked to reference signal “fref” when the phase difference or time difference between first control signal “/up” and the second control signal “/down” is smaller than the time interval of at least a half period of reference signal “fref”.

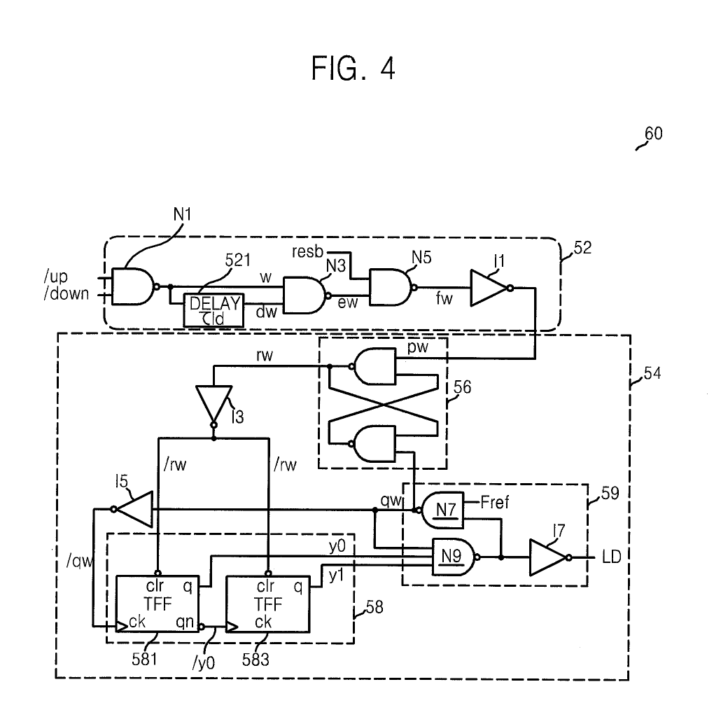

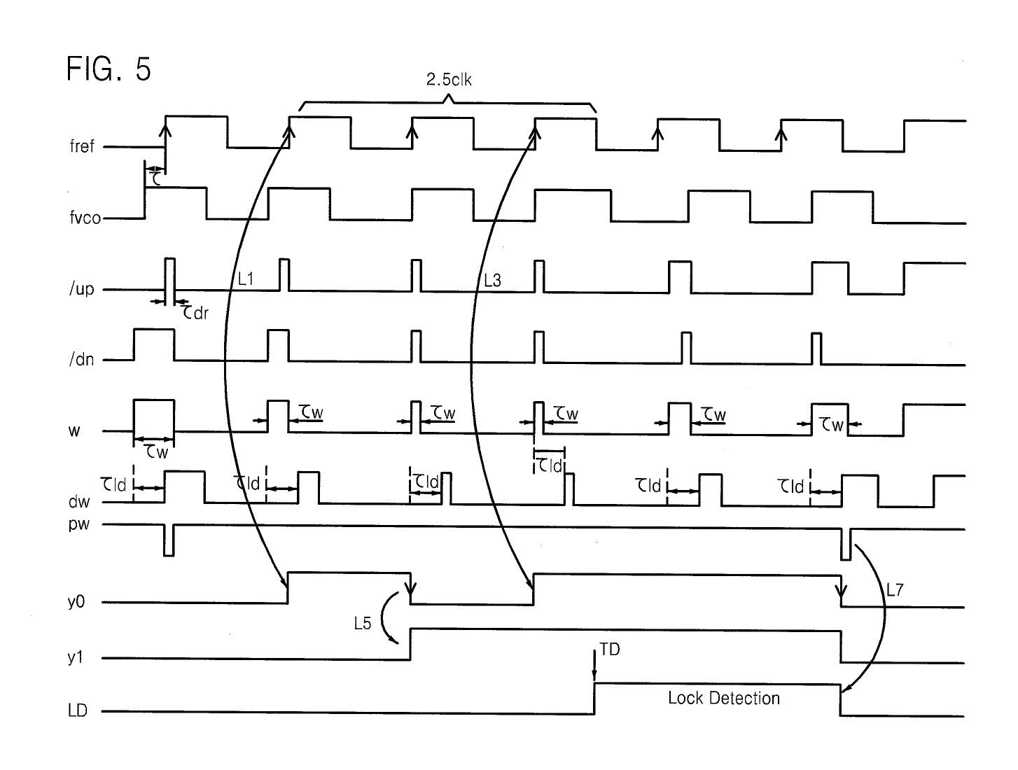

FIG. 4 is a circuit diagram of lock detector 60 of PLL 10 shown in FIG. 2 and FIG. 5 is an associated timing diagram showing the operation of PLL 10. Lock detector 60 includes time difference detection unit 52 and phase lock determination unit 54. Time difference detection unit 52 receives first control signal “/up” and second control signal “/down”, detects the time difference “Tw” between first control signal “/up” and second control signal “/down”, and compares the detected time difference “Tw” with the reference time “Tld”, and outputs a comparison signal “pw” corresponding to this comparison result. For example, when time difference “Tw” between first control signal “/up” and second control signal “/down” is less than the reference time “Tld”, comparison signal “pw” is in a first logic level state (high). When the time difference “Tw” between first control signal “/up” and second control signal “/down” is greater than the reference time “Ty ld”, comparison signal “pw” is in a second logic level state (low).

Time difference detection unit 52 includes a first NAND gate N1, delay block 521, second NAND gate N3, third NAND gate N5, and first inverter I1. First NAND gate N1 receives first control signal “/up” and second control signal “/down”, performs a NAND operation on the received signals, and outputs the result as first signal “w”. The time difference “Tw” corresponding to the pulse width of first signal “w” is a signal indicating a phase difference or time difference between first control signal “/up” and second control signal “/down”. This value is obtained by adding the reset delay time “Tdr” to time difference “T” between reference signal “fref” and feedback signal “fvco”. Delay block 521 receives first signal “w” and outputs second signal “dw” by delaying first signal “w” for the length of reference time “Tld”. Delay block 521 may embody at least one buffer.

Second NAND gate N3 receives first signal “w” and second signal “dw”, and outputs the NAND result as third signal “ew”. Third NAND gate N5 receives third signal “ew” and reset signal “resb”, and outputs the NAND result as fourth signal “fw”. First inverter I1 receives fourth signal “fw” and inverts this signal to output comparison signal “pw”. When the time difference “Tw” between first control signal “/up” and second control signal “/down” is smaller than reference time “Tld”, comparison signal pw is in the first logic level state (high). When time difference “Tw” between first control signal “/up” and second control signal “/down” is greater than reference time “Tld” then comparison signal pw is in the second logic level state (low). Phase lock determination unit 54 generates phase lock signal “LD” which is activated based on comparison signal “pw” when the time difference “Tw” is smaller than reference time “Tld” during the interval of at least a half period of reference signal “fref”.

Phase lock determination unit 54 includes latch circuit unit 56, toggle circuit unit 58, and logic circuit unit 59. Latch circuit unit 56 latches the comparison signal “pw” output from time difference detection unit 52 based on a first output signal “qw” of logic circuit unit 59. Latched signal “rw” can be output as signal “/rw” inverted by second inverter 13. The toggle circuit unit 58 includes first flip flop 581 and second flip-flop 583 and toggles reference signal “fref”. First flip-flop 581 latches the inverted first output signal “/qw” based on inverted first output signal “/qw”. First flip-flop 581 includes a clock port “ck” configured to receive inverted first output signal “/qw” of logic circuit unit 59. Reset port “clr” of flip-flop 581 receives inverted latch signal “/rw”. A first output port “q” of flip-flop 581 supplies output signal “y0”, and second output port “qn” outputs inverted output signal “/y0”. In this manner, first flip-flop 581 samples and outputs the level state of first output signal “/qw” in response to a rising edge of inverted first output signal “/qw”. Alternatively, first flip-flop 581 latches the level state of inverted first output signal “/qw” in response to a falling edge of inverted first output signal “/qw”. The inverted first output signal “/qw” has a logic level state corresponding to reference signal “fref” when phase lock signal “LD” is in the second logic level state (low). Thus, output signal “y0” of first flip-flop 581 is the same as toggling reference signal “fref” when the phase lock signal “LD” is in the second logic level state (low). For example, output signal “y0” of first flip-flop 581 samples and outputs the level state of reference signal “fref” in response to a rising edge of the reference signal “fref” when the comparison signal “pw” is in the second logic level state (low). The time difference “Tw” between first control signal “/up” and second control signal “/down” is greater than the reference time “Tld” (L1 and L3).

Second flip-flop 583 of toggle circuit unit 58 latches the inverted output signal “/y0” of first flip-flop 581. Second flip-flop 583 includes a clock port “ck” to receive the inverted output signal “/y0”, a reset port “clr” to receive the inverted latch signal “/rw”, and an output port “q” for output signal “y1”. Second flip-flop 583 samples and outputs the level state of the inverted output signal “/y0” of first flip-flop 581 in response to a rising edge of the inverted output signal “/y0” (L5). Alternatively, second flip-flop latches the level state of inverted output signal “/y0” of the first flip-flop 581 in response to a falling edge of the inverted output signal “/y0”.

Logic circuit unit 59 includes a fourth NAND gate N7, a fifth NAND gate N9, and a third inverter 17. Fourth NAND gate N7 receives reference signal “fref” and output signal “/LD” and outputs first output signal “qw”. Fifth NAND gate N9 receives first output signal “qw”, output signal “y0” from first flip-flop 581, and output signal “y1” from second flip-flop 583, and outputs second output signal “LD”. Third inverter 17 receives and inverts the second output signal “/LD” and outputs phase lock signal “LD”. In this manner, when the logic state of each of the signals “qw”, “y0”, and “y1” supplied to fifth NAND gate N9 is in the first logic level state (high), second output signal “/LD” is in the second logic level state (low) and phase lock signal “LD” is in first logic level state (high) so that the phase of PLL 10 is locked. By way of example, when comparison signal “pw” is in the first logic level state (high) for 2.5 clock cycles of reference signal “fref” shown in FIG. 5 where the time difference “Tw” between first control signal “/up” and second control signal “/down” is smaller than reference time “Tld”, phase lock signal “LD” is shifted from the second logic level state (low) to the first logic level state (high) (TD) and the phase of PLL 10 is locked. Conversely, when comparison signal “pw” is in the second logic level state (low), where the time difference “Tw” between first control signal “/up” and second control signal “/down” is greater than reference time “Tld”, phase lock signal “LD” is shifted from the first logic level state (high) to the second logic level state (low) and the phase of PLL 10 is unlocked. The phase lock interval is defined by reference time “Tld” which is locked. When the time difference “Tw” between the first control signal “/up” and the second control signal “/down” is greater than reference time “Tld”, an amount of internal jitter (Tw-Tld) may be measured. Thus, the phase lock determination unit 52 determines that PLL 10 is unlocked when the amount of jitter is greater than 0 and shifts comparison signal “pw” to the second logic level (low) to deactivate phase lock signal “LD”.

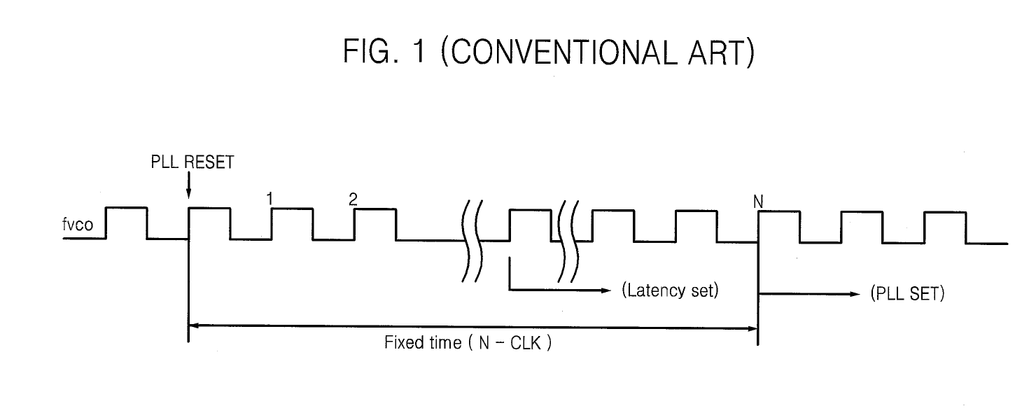

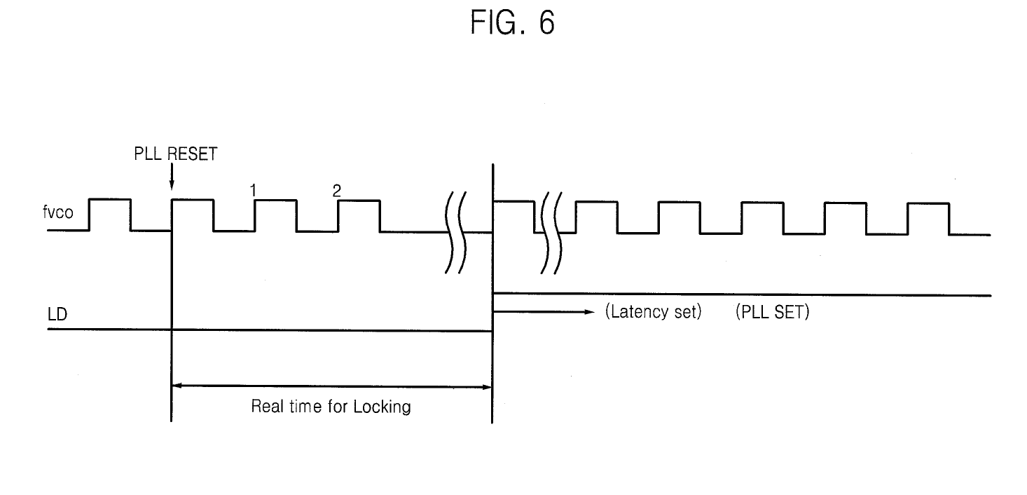

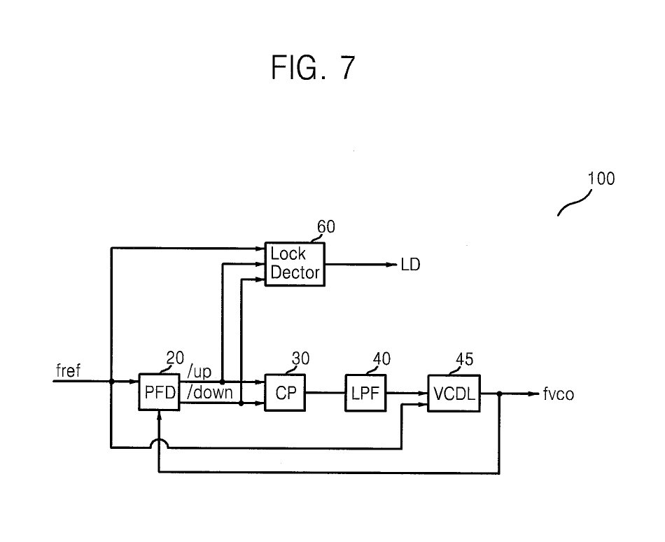

FIG. 6 is a timing diagram for explaining a phase lock time. After PLL 10 (of FIG. 1) is reset, the phase locked time is recognized in real time. Thus, the problem that remaining clocks cannot be used until the set phase lock time passes even though the phase of PLL or DLL is locked may be avoided. FIG. 7 is a functional block diagram of a DLL that includes a voltage controlled delay line (VCDL) 45 instead of VCO 50 as compared to PLL 10. VCDL 45 delays reference signal “fref” and generates output signal “fvco” based on an analog control voltage generated by LPF 40. Other than employing VCDL 45 instead of VCO 50, the structure and operation of DLL 100 is the same as or similar to that described with reference to PLL 10.

As described above, by utilizing a lock detection unit in a frequency regulator, the determination of whether the phase of PLL or DLL is locked may be made by using an internal signal of the PLL or DLL. In addition, the phase lock time can be measured and the internal latency can be accurately set. Also, since the phase lock of PLL or DLL is recognized in real time, it is easily determined whether the PLL or DLL is unlocked. Furthermore, the amount of jitter affecting the time difference between the reference signal and the output signal may be measured.

Although the present invention has been described in connection with the embodiments of the present invention illustrated in the accompanying drawings, it is not limited thereto. It will be apparent to those skilled in the art that various substitution, modifications and changes may be thereto without departing from the scope and spirit of the invention.

What is claimed is:

1. A frequency regulator comprising:
a phase frequency detector receiving a reference signal and a feedback signal, said phase frequency detector comparing a phase associated with said reference signal and a phase associated with said feedback signal and outputting a first control signal and a second control signal to regulate phase and frequency of said feedback signal; and
a lock detection unit coupled to said phase frequency detector and configured to generate a phase lock signal when a time difference between said first control signal and said second control signal is smaller than a reference time during an interval time period of at least a half period of said reference signal.

2. The frequency regulator of claim 1, wherein said frequency regulator is a PLL (phase locked loop) having a voltage controlled oscillator (VCO) configured to output said feedback signal.

3. The frequency regulator of claim 17 wherein said frequency regulator is a DLL (delay locked loop) having a voltage controlled delay line (VCDL) configured to output said feedback signal.

4. The frequency regulator of claim 1, wherein said lock detection unit further comprises:
a time difference detection unit detecting a time difference between said first control signal and said second control signal, said time difference detection unit configured to compare the detected time difference with said reference time and outputting a comparison signal; and
a phase lock determination unit coupled to said time difference detection unit and configured to generate said phase lock signal when a time difference between said first control signal and said second control signal is smaller than the reference time during an interval time period of at least a half period of said reference signal.

5. The frequency regulator of claim 4, wherein said time difference detection unit comprises:
a first NAND gate receiving said first control signal and said second control signal and outputting a NAND gate output signal;
a delay block coupled to said first NAND gate delaying said first NAND gate output signal for as long as said reference time;
a second NAND gate coupled to said first NAND gate and said delay block, said second NAND gate receiving said output from said first NAND gate and an output signal from said delay block; and
a first logic circuit unit outputting said comparison signal based on an output signal of said second NAND gate and a reset signal.

6. The frequency regulator of claim 5, wherein the first logic circuit unit comprises:
a third NAND gate coupled to and receiving said output signal from said second NAND gate and said reset signal; and
an inverter coupled to an output of said third NAND gate and receiving an output signal from said third NAND gate and outputting said comparison signal.

7. The frequency regulator of claim 4, wherein the phase lock determination unit comprises:
a latch circuit unit latching said comparison signal output from said time difference detection unit;
a toggle circuit unit coupled to said latch circuit unit configured to toggle said reference signal; and
a second logic circuit unit coupled to said latch circuit unit and said toggle circuit unit, said second logic circuit unit outputting said phase lock signal in response to an output signal from said toggle circuit unit and said reference signal.

8. A method for regulating a frequency, the method comprising:
receiving a reference signal and a feedback signal by a phase frequency detector;
comparing a phase associated with said reference signal and a phase associated with said feedback signal;
outputting a first control signal and a second control signal based on said comparison of said reference signal phase and said feedback signal phase to regulate phase and frequency of said feedback signal; and
generating a phase lock signal when a time difference between said first control signal and said second control signal is smaller than a reference time during an interval time period of at least a half period of said reference signal.

9. The method of claim 8, wherein generating a phase lock signal further comprises:
detecting a time difference between said first control signal and said second control signal;
comparing the detected time difference to said reference time and outputting a comparison signal; and
generating said phase lock signal when a time difference between said first control signal and said second control signal is smaller than said reference time during an interval time period of at least a half period of said reference signal.
